(19) United States
(12) Patent Application Publication
(10) Pub. No.: US 2007/0063876 A1
(43) Pub. Date: Mar. 22, 2007

(54) Multiple sensing element touch sensor

(76) Inventor: Alex K. Wong, Vancouver (CA)

Correspondence Address: 3M INNOVATIVE PROPERTIES COMPANY, PO BOX 33427, ST. PAUL, MN, 55133-3427, US

(21) Appl. No.: 11/210,541

(22) Filed: Aug. 24, 2005

(51) Int. Cl. H03K 17/94; H03M 11/00

(52) U.S. Cl. 341/34

(57) ABSTRACT

Disclosed are touch sensors that include a plurality of separated conductive sensing elements, controller electronics configured to determine touch position based on signals received from the conductive sensing elements in response to a touch, and a plurality of input leads connecting the conductive sensing elements to the controller electronics, each sensing element having multiple connections to one of the plurality of input leads to form multiple resistance pathways from each sensing element to the controller electronics.

The present disclosure relates to touch sensors that include multiple sensing elements to detect a touch.

### BACKGROUND

As computers and other electronic devices become more ubiquitous, touch-sensing systems are becoming more prevalent as a means for inputting data. For example, touch-sensing systems may now be found in workshops, warehouses, manufacturing facilities, restaurants, on hand-held personal digital assistants, automatic teller machines, casino game-machines, in automotive applications, and the like.

Capacitive touch sensing is one of the most widely used techniques in touch screen industries. Capacitive touch sensors are mainly divided in two groups, namely, analog capacitive sensors, which use a contiguous resistive layer, and projected capacitive sensors, which use discontinuous or patterned conductive layers. In an analog capacitive sensor, the contiguous resistive layer is excited from four corners so that a capacitively coupled touch input induces currents that can be measured, decoded and translated to positional coordinates. In a typical projected capacitive touch screen, the sensor employs a series of parallel conductors such as wires or bars that are driven with an excitation signal from a controller. The signals induced by a touch are transmitted to the controller with the same lead lines that excite the sensing elements. These signals are then decoded in the controller and the touch coordinates are reported to a computer.

### SUMMARY

Provided are touch sensors that include a plurality of separated conductive sensing elements, controller electronics configured to determine touch position based on signals received from the conductive sensing elements in response to a touch, and a plurality of input leads connecting the conductive sensing elements to the controller electronics, each sensing element having multiple connections to one of the plurality of input leads to form multiple resistance pathways from each sensing element to the controller electronics.

Also provided are touch sensor systems that include a touch sensor. The touch sensor has a plurality of separated conductive sensing elements, each spanning a sensing region from a first end to a second end, controller electronics configured to determine touch position based on signals received from the conductive sensing elements, and a plurality of input leads connecting the conductive sensing elements to the controller electronics, wherein the first end and second end of each sensing element is connected to the same input lead.

Further provided are methods for reducing time-dependent signal variations in response to a touch on a touch sensor having a plurality of separated conductive sensing elements, each spanning a sensing region from a first end to a second end. The methods include providing a plurality of lead lines, each lead line connected to one of a plurality of controller inputs, for each of the plurality of sensing elements connecting the first end and the second end to the same one of the plurality of lead lines, and providing controller electronics coupled to the controller inputs and configured to determine touch position based on signals generated when the touch is sensed by the conductive sensing elements.

The above summary is not intended to describe each embodiment or every implementation of the present disclosure. Advantages and attainments, together with a more complete understanding of the invention, will become apparent and appreciated by referring to the following detailed description and claims taken in conjunction with the accompanying drawing.

### BRIEF DESCRIPTION OF THE DRAWING

The invention may be more completely understood in consideration of the following detailed description of various embodiments of the invention in connection with the accompanying drawings, in which:

FIG. 1 is a schematic representation of input connections to a matrix of sensing elements.

FIG. 2(a) is a simplified equivalent circuit diagram for one of the sensing elements shown in FIG. 1.

FIG. 2(b) is another simplified equivalent circuit diagram for one of the sensing elements shown in FIG. 1, including a backshield guard drive.

FIG. 3 is a schematic representation of an input connection to a single sensing element according to the present disclosure.

FIG. 4 is a simplified equivalent circuit diagram for the sensing element shown in FIG. 3.

FIG. 5 is schematic representation of one example of a sensing element layout according to the present disclosure.

FIG. 6 is a schematic side view of a sensor construction usable in the present disclosure.

FIG. 7 is a schematic block diagram of a system that can utilize a sensor of the present disclosure.

### DETAILED DESCRIPTION

The present disclosure generally relates to touch sensors that utilize multiple conductive sensing elements to detect a touch input and to determine information related to a touch such as touch position. In particular embodiments, the present disclosure relates to touch sensors that utilize multiple elongated conductive sensing elements such as a plurality of separated parallel bars, stripes, traces, wires, or other patterns, and particularly to those with high resistivity. Multiple sensing element touch sensors can include capacitive touch screens in which the sensing elements couple to the touch object, and resistive touch screens in which sensing elements couple to other sensing elements in response to a touch.

In multiple sensing element touch sensors, the finite electrical resistance of the conductive sensing elements can introduce time delays during the excitation and sampling of the sensing elements by the controller electronics. Other time-dependent variations can also occur, such as undesired phase shifts and/or signal amplitude variations. Such time-dependent signal variations can cause errors when determining information related to touch inputs. According to the present disclosure, forming multiple connections between a sensing element and a single controller input provides pathways from the sensing element to the controller having reduced resistance, resulting in lower impedance connections that can improve response times and provide more uniform signals to improve touch information determinations. For example, connecting the same controller input to both ends of an individual sensing element can reduce the reactive time delay constant and other time-dependent signal variations.

As described, multiple sensing element touch sensors can be capacitive or resistive. In systems where the sensor layout includes a series of parallel sensing elements, the sensing elements can be used to determine touch position in a direction perpendicular to the sensing elements. As such, a single set of parallel sensing elements can be used to detect touch position in one direction, and two overlapping and differently oriented sets of parallel sensing elements can be used to detect touch position in two directions.

For the sake of clarity and without the loss of generality, consider capacitive touch sensors having sensing elements laid out in an x-y grid; with the x-axis sensing elements sufficiently insulated from the y-axis sensing elements, for example by an insulating substrate, by an adhesive, by discrete insulators formed in the overlap areas, or the like. In known screens of this type, one end of each sensing element is connected to the input of the controller electronics, and the other end remains floating.

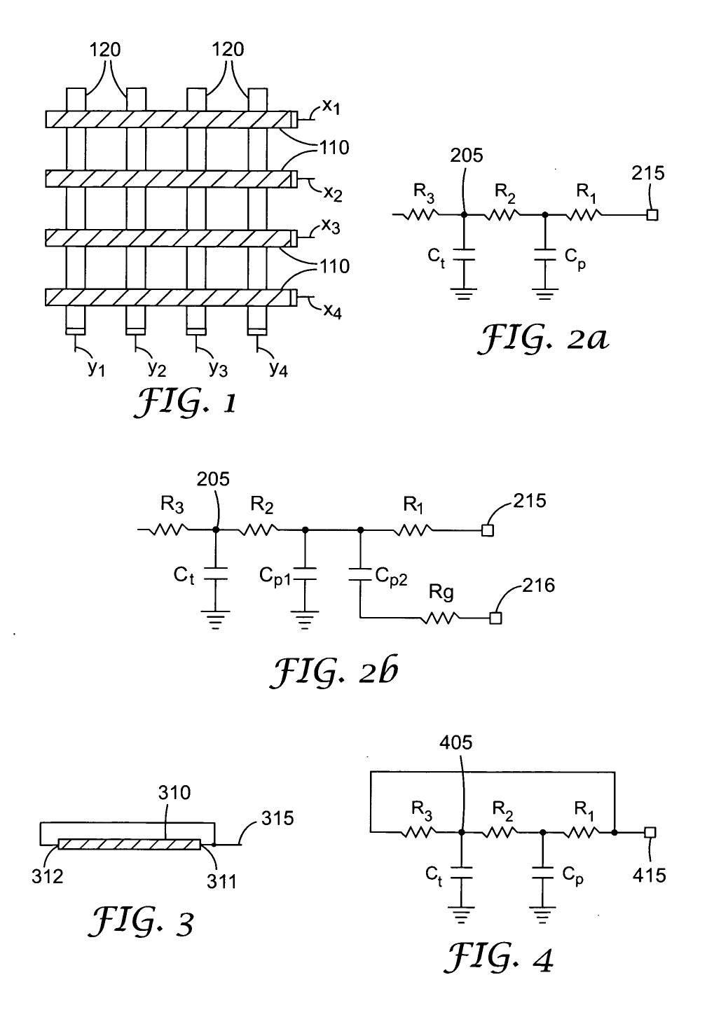

FIG. 1 schematically shows such a matrix configuration having a series of x-bars 110 and a series of y-bars 120, each x-bar connected to an input lead (labeled x₁-x₄) on one end only and each y-bar connected to an input lead (labeled y₁-y₄) on one end only. Various sensor configurations and corresponding touch detection techniques include those disclosed in U.S. Pat. Nos. 4,582,955; 4,659,874; 4,686,332; 4,778,951; 5,374,787; 5,418,551; 5,650,597; 5,844,506; 6,137,427; 6,297,811; 6,762,752; and 6,825,833, and International Publication WO 96/15464 A1, each of which is wholly incorporated into this document. As appreciated in the present disclosure, when the sensing elements of such sensor configurations have an appreciable resistance (e.g., resistivity measured in tens or hundreds of ohms per square or more, recognizing that for larger touch screens, even smaller resistivities can cause time delays or other undesirable time-dependent signal variations), the resistance of the sensing elements combined with the touch capacitance and parasitic capacitances can cause undesirable delay or other time-dependent variations during acquisition of a touch signal by the controller.

As schematically shown in the simplified equivalent circuit diagram of FIG. 2(a), a touch at point 205 creates a touch capacitance Cₜ on the sensing element represented by R₁, R₂ and R₃, resulting in the controller detecting the touch signal through input 215 with a time delay caused by the effective resistance R_{eff}=R₁+R₂. There is also a time delay caused by resistance R₁ and parasitic capacitance(s) modeled by Cₚ, which can represent coupling to any of a number of objects such as a proximate display, bezel, backside guard, and the like. While Cₚ is shown to be localized for the sake of simplicity, it is in fact distributed over the entire sensing element. A particularly common parasitic capacitance involves coupling to the sensor's backside guard. FIG. 2(b) schematically shows a circuit diagram like that in FIG. 2(a), and which indicates two parasitic capacitances, Cₚ₁ and Cₚ₂, which are distributed along the sensing element, although shown as localized for the sake of simplicity. The distributed parasitic capacitance modeled by Cₚ₂ represents coupling to a backside guard drive 216 through guard resistance R_{g}.

In circuits like those shown in FIGS. 2(a) and 2(b), the total time delay will be proportional to the amount of capacitance and the effective resistance of the sense element that the controller sees at its inputs. That is, the delay is a function of both the touch capacitance and the location of the touch along the sensing element, so that the larger the touch capacitance and the farther away the touch is from the input end of the sensing element, the longer the time delay. If the controller is not configured to account for the worst-case delay during signal acquisition, touch information errors can occur (touch position, size of touch coupling area, etc.). Similar considerations apply for other time-dependent signal variations.

To reduce the effective resistance seen by the controller electronics, and therefore to reduce the time delay and other time-dependent signal variations, systems of the present disclosure provide multiple connections between the sensing element and the controller input, for example connecting both ends of an elongated sensing element to a single input that feeds into the controller. FIG. 3 schematically shows a single sensing bar 310 and a single controller input 315 that connects to both ends 311 and 312 of the sensing bar 310. The distance spanned by the bar 310 from the first end 311 to the second end 312 can be referred to as the sensing region of the bar.

FIG. 4 shows a simplified equivalent circuit for the connection shown in FIG. 3 where a touch at point 405 breaks up the sensing element into multiple resistance paths. In this case, because the sensing element is connected at both ends to the controller input 415, there is an additional resistance path, resistance R₃, that provides a shorter time delay when analogously compared to the situation shown in FIG. 2. As a result of reducing the time delay by providing a lower resistance path, the time needed for the controller to acquire the touch signal is reduced and overall touch response time can be improved. Reduced average time delay also allows for more time to achieve stable signal quiescence, and thus achieve a higher degree of accuracy more consistently.

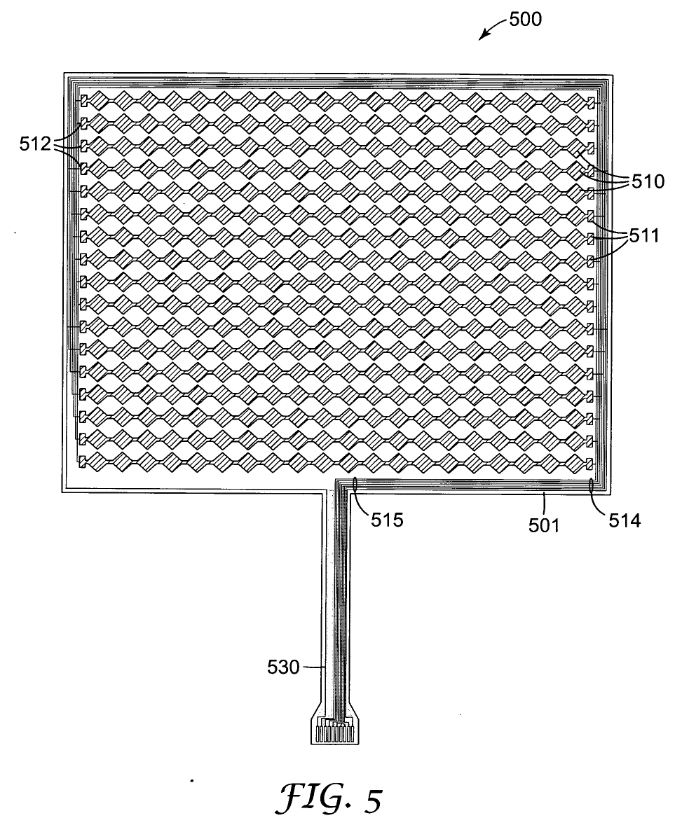

FIG. 5 shows an example of a sensing element layout for a capacitive touch sensor 500. Touch sensor 500 includes a substrate 501 onto which is formed a series of sensing elements 510 laid out in a parallel arrangement of separated horizontal traces each having a right end 511 and a left end 512. Lead lines 514 connect the sensing elements 510 to controller input leads 515. The substrate 501 can be any suitable substrate such as glass or plastic film, for example polyethylene terapthalate (PET). The sensing elements can include any suitable conductive materials such as transparent conductive oxides, for example indium tin oxide (ITO), tin antimony oxide (TAO), or other doped tin oxides, conductive polymers, carbon black, metal traces, and so forth. The lead lines 514 and input leads 515 can be provided from any suitable conductive material, for example silver paste or the like. In transparent sensor embodiments, the lead lines 514 and input leads 515 can be provided in a border area outside of the active touch input area so that they are not visible when viewing a display through the touch sensor. The sensing elements and lead lines can be formed or disposed on the substrate by any suitable method including selective deposition, screen printing, ink jet printing, gravure printing, photolithography, etching, masking techniques, and so forth.

In the layout shown in FIG. 5, each sensing element 510 is characterized by a series of linearly connected diamond shapes, the diamond shapes in each row lining up so that diamond-shaped interstices, or windows, are formed by each set of four neighboring diamonds. A similar series of vertically oriented linearly connected diamond traces can be arranged so that the diamonds of the vertical traces fit within the windows formed by the diamonds of the horizontal traces, for example to allow for more effective coupling of touch objects to vertical sensing elements that are positioned underneath horizontal sensing elements in the sensor construction. In such configurations having a second set of diamond-shaped sensing elements under the first, the second set of diamonds can be made somewhat larger than the first to increase the coupling area in compensation for the increased distance (and thus lower coupling strength) between the touch input and the second set of sensing elements.

Referring again to FIG. 5, the left end 512 and right end 511 of each sensing element is connected to the same one of the set of lead lines 514. Such “dual end connecting” to a common input creates multiple resistance paths to the controller so that the overall resistance is reduced. Each lead line 514 is connected to a controller input 515, the controller inputs connecting to the controller electronics (not shown) using an electronic tail 530. Connections on the sensor between the sensing elements and lead lines can be made through vias in an insulative material, for example an insulator disposed over the lead lines, in a manner similar to that employed in multilayer circuitry.

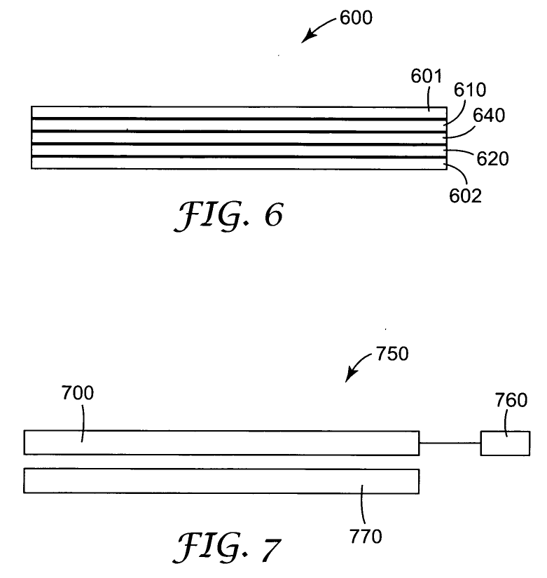

FIG. 6 schematically indicates a layer construction for a touch sensor 600 useful in the present disclosure, including a first conductive trace layer 610 on a first substrate 601, a second conductive trace layer 620 on a second substrate 602, and an adhesive layer 640 bonding the first conductive trace layer and substrate to the second conductive trace layer and substrate. The entire sensor construction 600 can then be laminated to a rigid substrate such as glass, or incorporated into a display system directly. Each of substrate 601 and substrate 602 can be any suitable material, for example a flexible sheet such as PET. Any adhesive layers bonding the substrates or bonding the construction to a rigid substrate or display system can include any suitable adhesive. For transparent sensor embodiments, optical adhesives such as those provided by 3M Co., St. Paul, Mn. can be suitably used. Exemplary layer constructions also include those disclosed in U.S. Publication 2005/0083307, which is wholly incorporated into this document.

FIG. 7 schematically shows a touch system 750 that includes a touch sensor 700 coupled to touch controller electronics 760 and disposed over a display device 770. Touch sensor 700 can be transparent so that display device 770 can be viewed through the touch sensor. Display device 770 can be a changeable electronic display, such as a cathode ray tube (CRT), liquid crystal display (LCD), or so forth, can be static graphics or the like, or can be a combination of both.

The foregoing description has been presented for the purposes of illustration and is not intended to be exhaustive or to limit the invention to the precise form disclosed. Many modifications and variations are possible in light of the above teaching. It is intended that the scope of the invention be limited not by this detailed description, but rather by the claims appended hereto.

We claim:

1. A touch sensor system comprising a touch sensor that comprises:
a plurality of separated conductive sensing elements, each spanning a sensing region from a first end to a second end;
controller electronics configured to determine touch position based on signals received from the conductive sensing elements; and
a plurality of input leads connecting the conductive sensing elements to the controller electronics, wherein the first end and second end of each sensing element is connected to the same input lead.

2. The touch sensor system of claim 1, wherein the plurality of separated conductive sensing elements comprises a series of parallel conductive bars.

3. The touch sensor system of claim 1, wherein the plurality of separated conductive sensing elements comprises a first series of parallel conductive bars and a second series of parallel conductive bars oriented orthogonally to, and electrically insulated from, the first series.

4. The touch sensor system of claim 1, wherein each of the plurality of separated conductive sensing elements comprises a linearly connected series of diamond shapes.

5. The touch sensor system of claim 1, wherein the touch sensor is a capacitive touch sensor.

6. The touch sensor system of claim 1, wherein the touch sensor is a resistive touch sensor.

7. The touch sensor system of claim 1, wherein the touch sensor senses touch position in at least one direction.

8. The touch sensor system of claim 1, wherein the touch sensor senses touch position in two directions.

9. The touch sensor system of claim 1, further comprising a display positioned to be viewable through the touch sensor.

10. A method for reducing time-dependent signal variations in response to a touch on a touch sensor having a plurality of separated conductive sensing elements, each spanning a sensing region from a first end to a second end, the method comprising:
providing a plurality of lead lines, each lead line connected to one of a plurality of controller inputs;
for each of the plurality of sensing elements, connecting the first end and the second end to the same one of the plurality of lead lines; and
providing controller electronics coupled to the controller inputs and configured to determine touch position based on signals generated when the touch is sensed by the conductive sensing elements.

11. The method of claim 10, wherein the time-dependent signal variations are reactive time delays.

12. A touch sensor comprising:
a plurality of separated conductive sensing elements;
controller electronics configured to determine touch position based on signals received from the conductive sensing elements in response to a touch; and
a plurality of input leads connecting the conductive sensing elements to the controller electronics, each sensing element having multiple connections to one of the plurality of input leads to form multiple resistance pathways from each sensing element to the controller electronics.
